(19) United States
(12) Patent Application Publication
(10) Pub. No.: US 2002/0121683 A1
(43) Pub. Date: Sep. 5, 2002

(54) Encapsulated die package with improved parasitic and thermal performance

(76) Inventors: Stephen G. Kelly, Melrose, MA (US); Kenneth R. Philpot, Nashua, NH (US); Henricus Bernadus Antonius Giesen, Didam (NL); William E. Doherty JR., Bedford, MA (US)

Correspondence Address: Michael G. Cameron, Jackson Walker LLP., Suite 600, 2435 North Central Expressway, Richardson, TX, 75080, US

(21) Appl. No.: 10/085,164

(22) Filed: Feb. 26, 2002

Related U.S. Application Data
(60) Provisional application No. 60/271,940, filed on Feb. 27, 2001.

(51) Int. Cl. H01L 23/495; H01L 23/36

(52) U.S. Cl. 257/675; 257/712; 257/713; 257/787; 438/123; 438/124; 438/122; 257/100

(57) ABSTRACT

An semiconductor device package (10) with improved thermal properties that limits unwanted parasitics and provides a more consistent distribution of parasitics from one device to another. The package of the present invention (10) is extremely compact and uses, in one embodiment, a minimal length of bond wires (20 and 22) between the terminals (14 and 16) and the attached device (30). The path length of the package (10) is reduced so as to represent only some fraction of a wavelength relative to the terminals (14 and 16) of the package (10). By reducing the length of the bond wires (20 and 22) and selecting the appropriate dielectric constant of the encapsulant (12), the invention provides a package (10) with a unique hexagonal structure that limits the effects of parasitics and provides good thermal dissipation. In a second and third embodiment of the present invention, the semiconductor device package (10) is useful in optoelectronic devices such light emitting diodes with an anode (71) and a cathode (72). The use of the novel design in this implementation also improves thermal properties and limits unwanted parasitics.

### CROSS REFERENCE TO RELATED APPLICATIONS

This application claims priority of U.S. Provisional Patent Application No. 60/271,940 filed on Feb. 27, 2001 entitled “Encapsulated Die Package with Improved Parasitic and Thermal Performance”, and the teachings are incorporated herein by reference.

### TECHNICAL FIELD

The present invention relates to an enclosure for a semiconductor device and, more specifically, to an encapsulated molded common leadframe package. More specifically, the invention relates to such a package that limits unwanted parasitics and provides excellent thermal dissipation. The package is useful in three lead devices and two lead devices, including optoelectronic devices such as light emitting diodes.

### BACKGROUND OF THE INVENTION

In surface mount assembly, it is common to provide an enclosure or housing for encapsulating a semiconductor device. Currently, numerous package styles are available for surface mount assembly, such as the Standard Outline Transistor 23 (SOT 23), and the Standard Outline Diode 323 (SOD 323). These common leadframe injection molded packages have been used in the industry for many years. However, such package styles suffer from various shortcomings including the existence of parasitics that limit the operating performance of the device past certain high frequencies. With such standard leadframe packages, the parasitics become inconsistent so that the distribution of parasitics varies from package to package. The result is that circuits and designs utilizing such packages tend to have inconsistency in performance with the results exaggerated as operating frequencies increase.

Moreover, standard package styles can suffer from very poor thermal paths between the surface upon which the semiconductor device is mounted and the thermal ground that provides attachment to the outside world, typically a circuit board. Accordingly, a need exists for a package style for a semiconductor device that provides good thermal properties and improved parasitic performance at higher operating frequencies.

### SUMMARY OF THE INVENTION

The present invention provides a semiconductor device package with improved thermal properties that limits unwanted parasitics and provides a more consistent distribution of parasitics from one device to another. Furthermore, the present invention provides a package with improved power handling capabilities or dissipation. Essentially, the package of the present invention is extremely compact and uses minimal length of bond wires between the terminals and the attached device. The path length of the package is reduced so as to represent only some fraction of a wavelength relative to the terminals of the package. By reducing the length of the bond wires and selecting the appropriate dielectric constant of the encapsulant, the invention provides a package with a unique hexagonal structure that limits the effects of parasitics and provides good thermal dissipation. The package is useful with optoelectronic devices such as light emitting diodes where the encapsulant material is made of a substantially clear, including translucent, epoxy.

### BRIEF DESCRIPTION OF THE DRAWINGS

For a better understanding of the invention including its features, advantages and specific embodiments, reference is made to the following detailed description along with accompanying drawings in which:

FIG., 1 is a perspective view of a first embodiment of the semiconductor device package of the present invention;

FIG. 2 is a top view of a first embodiment of the package, according to the invention, illustrating the arrangement of input/output and ground terminals;

FIG. 3 is a side view of a first embodiment of the package of the present invention illustrating the connection of wire bonds from terminal to semiconductor die;

FIG. 4 shows an alternate side view of a first embodiment of the package of the present invention;

FIGS. 5A, 5B and 5C illustrate close-up views of a first embodiment of the package of the present invention with dimensions noted thereon;

FIGS. 6A, 6B and 6C illustrate close-up views of a first embodiment of the package of the present invention with dimensions noted; and

FIGS. 7A, 7B, 7C and 7D illustrate close up views of the package according to a second embodiment of the package of the present invention with dimensions noted.

FIGS. 8A, 8B and 8C illustrate close up views of the package according to a third embodiment of the package of the present invention with dimensions noted.

FIGS. 9A, 9B and 9C illustrate views of the package according to the second and third embodiments of the package of the present invention with dimensions noted.

References in the detailed description correspond to like references in the figures unless otherwise noted.

### DETAILED DESCRIPTION OF EMBODIMENTS

While the making and using of various embodiments of the present invention are discussed in detail below, it should be appreciated that the present invention provides many applicable inventive concepts which can be embodied in a wide variety of specific contexts.

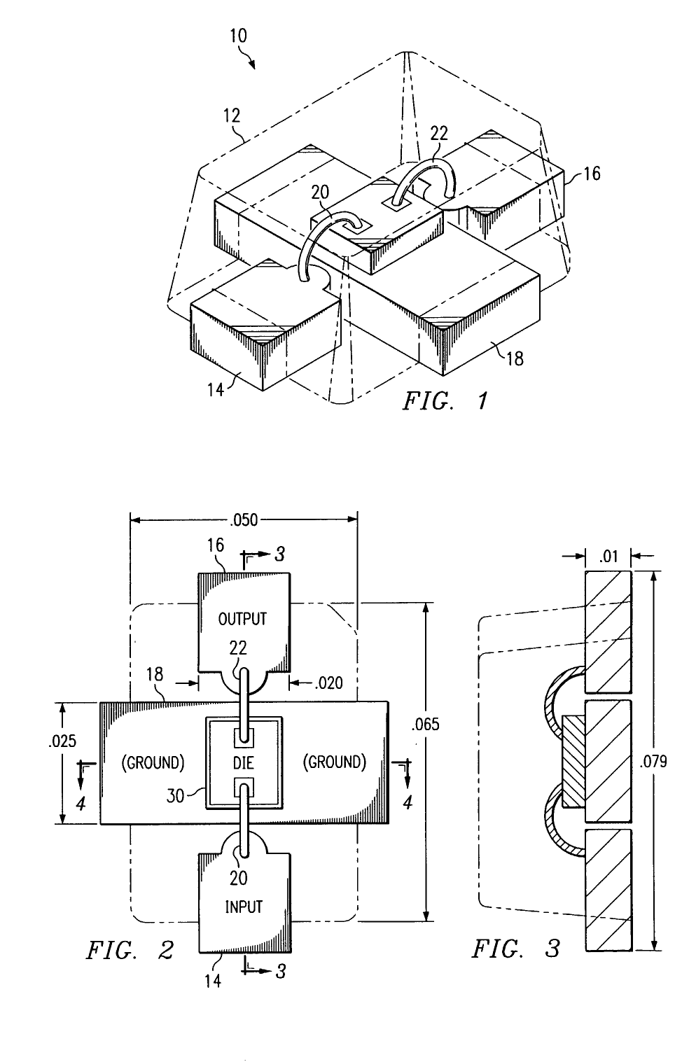

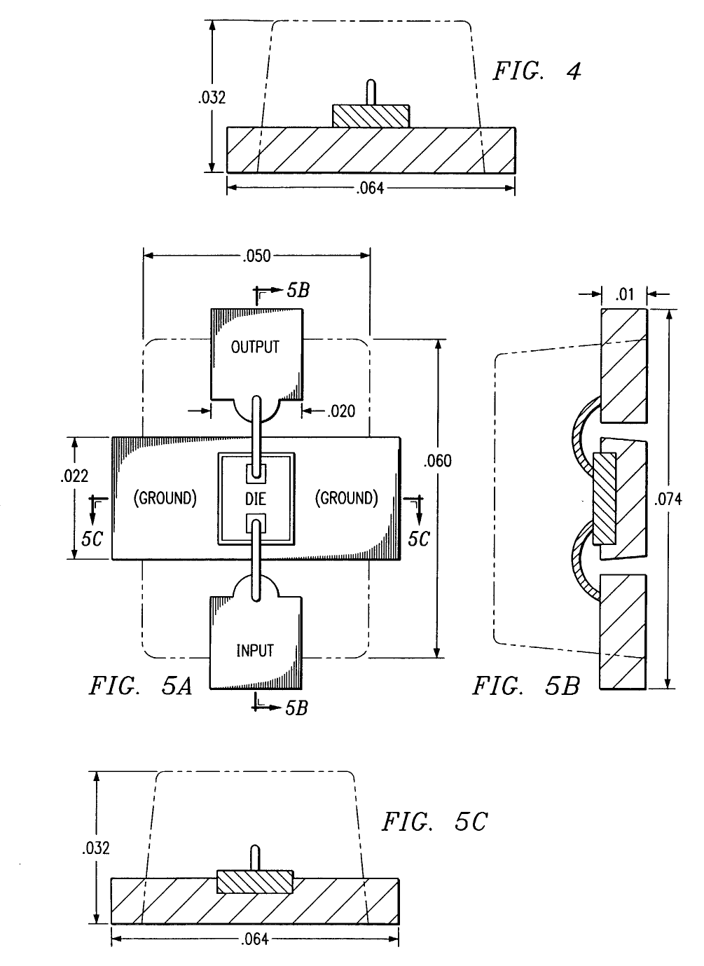

The present invention provides a package suitable for use in housing a semiconductor device, including as part of an integrated circuit, in a surface mount assembly. FIG. 1 illustrates a first embodiment of the package 10 as including an encapsulant material 12 with input terminal 14, output terminal 16 and ground terminal 18. As shown in FIGS. 2 and 3, a first embodiment of the package 10 is arranged so that bond wires 20 and 22 extend from terminals 14 and 16, respectively, and are attached to a semiconductor device 30 attached to an upper surface of the ground terminal 18.

The bond wires are maintained at a minimal length and the dielectric constant of the encapsulant material 12 is selected such that the performance of the device 10 is predictable, therefore enhancing the ability of the device 10 to minimize unwanted parasitics as the frequency of operation of signals coupled to the input terminal 14 increases. This enhances the consistency of the package 10 from one device to another. As illustrated in FIG. 1, the encapsulant material 12 has taken the form of a hexagonal structure that allows the use of the ground terminal 18 as a shunt comprising the surface where the device 30 is mounted. This surface wraps around the ground terminal 18 essentially at right angles and reaches down to the bottom surface, greatly enhancing the thermal path to ground. This results in overall less thermal capacitance and considerably less thermal resistance.

As is well known in the arts, the power handling capabilities of a semiconductor package depend on how much heat can be dissipated by the device. Too much heat can interfere with the operation of the semiconductor device 30, and as such, heat dissipation is a property of the package 10 that must be controlled accurately. As shown in FIGS. 2, 5A and 6A, a first embodiment of the package 10 includes conductive leadframe portions in the form of input terminal 14 and output terminal 16 such that power is applied to one side (the input terminal 14) to the device 30 and is output on an opposite side (the output terminal 16). Running approximately orthogonal to the input 14 and output 16 terminals is the ground terminal 18 which provides a shunt extending around the terminal 18, such that the electrical properties of the device 10 are controlled.

Since the bond wires 20 and 22 are kept short, package performance from one device to another is more consistent compared to SOT 23 and SOD 323 type packages. Also, since the parasitic capacitance is a function of dielectric constant of the encapsulant material 12, its performance is further improved and more predictable. The input and output terminals 14 the 16 are not parallel to each other, therefore avoiding parallel conductive surfaces which could create unwanted parasitics. Also, the input 14 and output 16 terminals have a rounded portion 24 and 26 which allow the length of the bond wires 20, 22 to be relatively short and further improves the performance of the device 10.

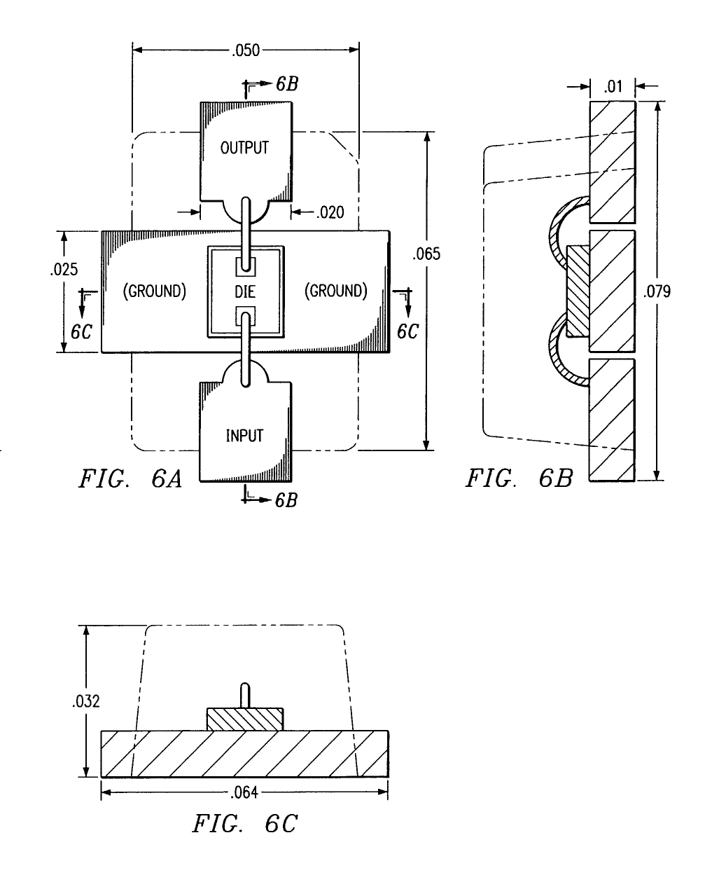

FIGS. 5A, 5B, 5C, 6A, 6B and 6C illustrate dimensions of the device, according to the first embodiment. It should be understood that changes to these dimensions can and will occur to those of ordinary skill in the art.

Therefore, the package 10 includes a unique orthogonal leadframe configuration which allows direct dissipation shunting to thermal ground while providing low inductance electrical connections to die which supports device functionality. In one embodiment, the device 10 operates with good results up to 10 gigahertz. Furthermore, the device 10 provides controlled dielectric constant encapsulant 12 which results in improved unit-to-unit and run-to-run package parasitic consistency. This results in improved RF performance consistency. Moreover, the package mounting footprints allows for visual confirmation of solder fillet, unlike flip-chip package designs which result in a blind solder joint. The package 10 allows for single or dual two-terminal devices (as noted below), three-terminal devices, as. well as gain stages. The unusually thick leadframe material allows a dovetail type of side edge so the epoxy can lock on the leads on only three sides. This is accomplished with unique half edge features which allow a mold with one side of the leadframe remaining completely bare copper. Because of the uniqueness of the assembly process, the package 10 allows the thermal path of the die to be outstanding. The full metal bottom allows the heat to transfer directly to a printed circuit board. Leadframe design allows wire bond wires 20, 22 to be extremely short for the package size.

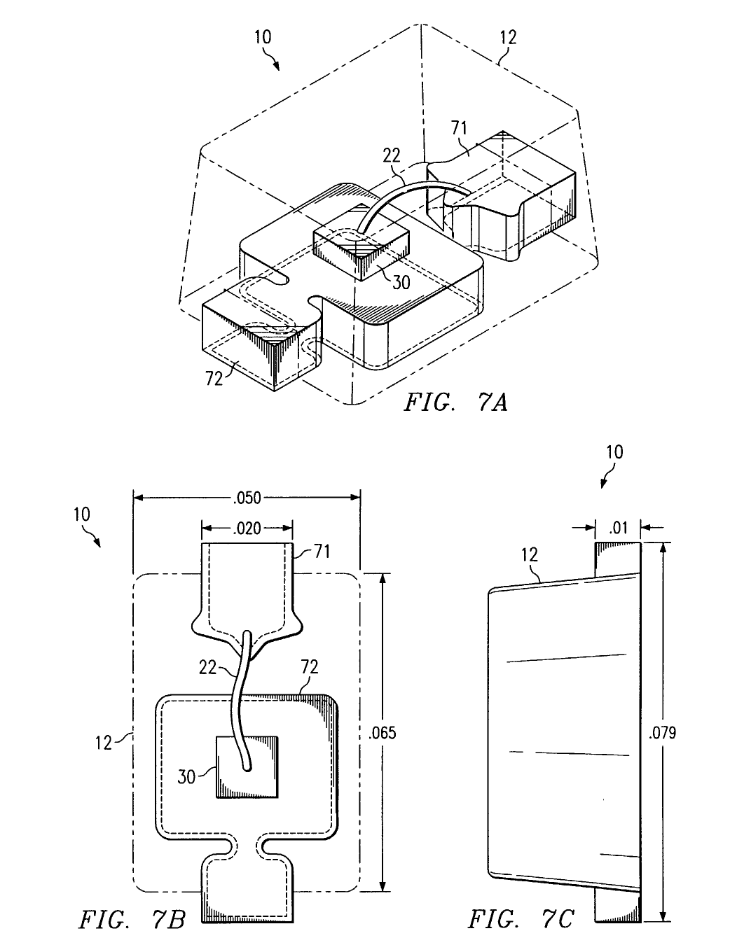

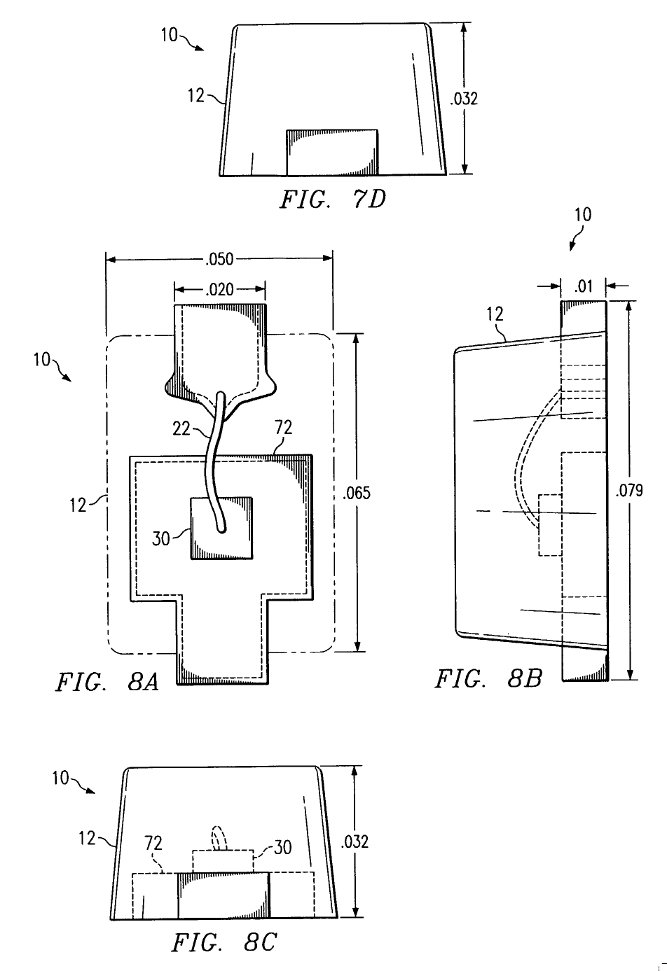

FIGS. 7A, 7B and 7C illustrate a second embodiment of the present invention for use with two lead devices, including optoelectronic devices such as light emitting diodes. As seen in FIG. 7A, if the two lead device is a light emitting diode, then encapsulant material 12 is made of a substantially clear epoxy, with anode 71 and cathode 72. As illustrated therein, the substantially clear encapsulant material 12 has taken the form of a hexagonal structure. The surface of the encapsulant wraps around the anode 71 and cathode 72 and reaches down to the bottom surface, greatly enhancing the thermal path to ground. Further, as can be seen in FIG. 7B, the anode 71 and the cathode 72 are positioned opposite to each other, with the cathode 72 further comprising a portion of a conductive lead-frame. The anode 71 has a shaped end surface operable to minimize parasitic capacitance. Alternatively, the cathode 72 could comprise metallization as the means of coupling the cathode 72 to the semiconductor die 30. As seen in FIG. 7B, a bond wire 22 couples the anode 71 to the semiconductor die 30. The bond wire 22 could have a length comprising a fraction of the wavelength for which frequency the semiconductor device 70 is designed. The packaged semiconductor device 10 as seen in FIG. 7A is adapted for use in an integrated circuit and is advantageously suited for use in a surface mount assembly. This configuration of the semiconductor device 10 as seen in FIG. 7A results in overall less thermal capacitance and considerably less thermal resistance.

FIGS. 8A, 8B and 8C illustrate a third embodiment of the present invention also for use with two lead devices, including optoelectronic devices such as light emitting diodes. As seen in FIG. 8A, encapsulant material 12 is also made of a substantially clear epoxy, with anode 71 and cathode 72. As distinguished from FIG. 7B, in FIG. 8B, the anode 71 comprises a portion of a conductive lead-frame. The cathode 72 has a shaped end surface operable to minimize parasitic capacitance. Alternatively, the anode 71 could comprise metallization as the means of coupling the anode 71 to the semiconductor die 30. As seen in FIG. 8B, a bond wire 22 couples the cathode 72 to the semiconductor die 30. The bond wire 22 could have a length comprising a fraction of the wavelength for which frequency the semiconductor device is designed. The packaged semiconductor device 10 as seen in FIG. 8A can be adapted for use in an integrated circuit and for use in a surface mount assembly. This configuration of the semiconductor device 10 as seen in FIG. 8A results in overall less thermal capacitance and considerably less thermal resistance.

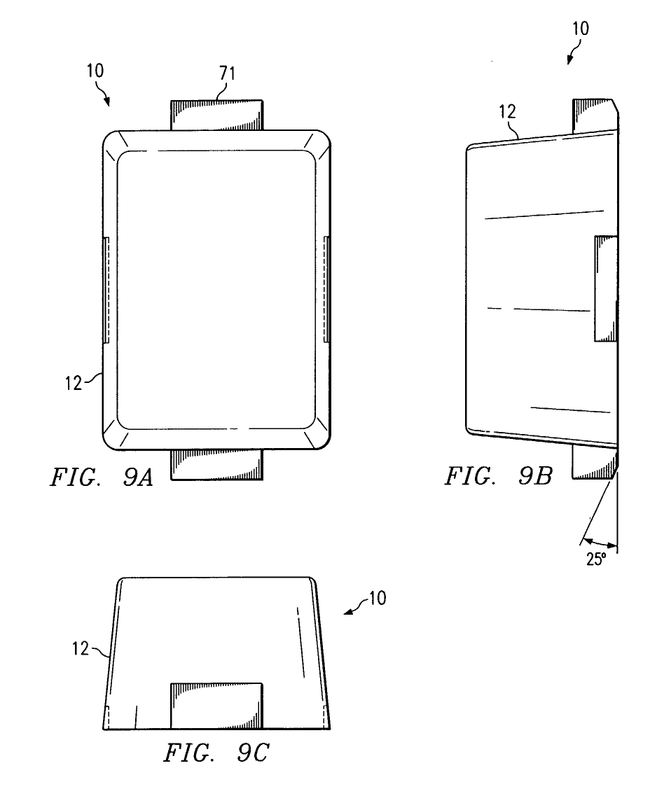

FIGS. 7B, 7C and 7D illustrate representative dimensions of the device, according to the second embodiment of the present invention. FIGS. 8A, 8B and 8C illustrate representative dimensions of the device, according to the third embodiment of the present invention. FIGS. 9A, 9B and 9C illustrate representative dimensions of the device, according to the second and third embodiments of the present invention. It should be understood that changes to these dimensions can and will occur to those of ordinary skill in the art.

While the invention has been described with regard to specific and illustrative embodiments, this description and the following claims are not intended to be construed in a limiting sense. Various modifications and combinations of the illustrative embodiments as well as other embodiments of the invention will become apparent to persons skilled in the art upon reference to the description and is intended that such variations be encompassed and included within the meaning and scope of the following claims.

What is claimed is:

1. A packaged semiconductor device, comprising:
a semiconductor die;
a substrate, with the semiconductor die disposed therein;
a plurality of leads coupled to the semiconductor die;
an encapsulant enclosing the semiconductor die and plurality of leads; and
the encapsulant operable to shunt thermal capacitance and thermal resistance away from the semiconductor die.

2. The packaged semiconductor device as recited in claim 1, further comprising an I/O common terminal, at least one input terminal and at least one output terminal, coupled to the semiconductor die.

3. The packaged semiconductor device as recited in claim 2, wherein the input terminal(s) and output terminal(s) are positioned orthogonal to the I/O common terminal.

4. The packaged semiconductor device as recited in claim 3, wherein the semiconductor die is positioned above the I/O common terminal.

5. The packaged semiconductor device as recited in claim 4, wherein the encapsulant forms a substantially hexagonal structure surrounding the I/O common terminal, input terminal(s), and output terminal(s), essentially at right angles with respect to the substrate.

6. The packaged semiconductor device as recited in claim 5, further comprising a lead-frame for coupling the input terminal(s) to a circuit and the output terminal(s) to a circuit.

7. The packaged semiconductor device as recited in claim 6, wherein the portion of the lead-frame coupled to each of the input terminal(s) and output terminal(s) possess exposed dovetailed side edges operable to allow epoxy to lock on the sides and top of the exposed edges.

8. The packaged semiconductor device as recited in claim 3, further comprising an end surface of the input terminal(s) being positioned adjacent and parallel to the side surface of the I/O common terminal, and an end surface of the output terminal(s) being positioned adjacent and parallel to the opposing side surface of the I/O common terminal, said end surfaces being shaped so as to minimize parasitic capacitance.

9. The packaged semiconductor device as recited in claim 8, further comprising a rounded shape on the end surface of the input terminal(s) positioned adjacent and parallel to the side surface of the I/O common terminal, and on the end surface of the output terminal(s) positioned adjacent and parallel to the opposing side surface of the I/O common terminal.

10. The packaged semiconductor device as recited in claim 8, further comprising length and width dimensions of approximately 0.079 millimeters and 0.065 millimeters and a height dimension of approximately 0.032 millimeters.

11. The packaged semiconductor device as recited in claim 8, further comprising an operating frequency range from DC to 10 gigahertz.

12. The packaged semiconductor device as recited in claim 8, further comprising use in a surface mount assembly.

13. The packaged semiconductor device as recited in claim 8, further comprising use in an integrated circuit.

14. The packaged semiconductor device as recited in claim 8, further comprising use in an amplifier gain stages.

15. The packaged semiconductor device as recited in claim 8, further comprising metallization, including a first and second metallization strip, as the means of coupling the input terminal(s) and the output terminal(s) to the semiconductor die.

16. The packaged semiconductor device as recited in claim 15, further comprising a path length from input terminal to the output terminal, of a fraction of the wavelength for which frequency the semiconductor device is designed.

17. The packaged semiconductor device as recited in claim 8, further comprising bond wires as the means of coupling the input terminal(s) and the output terminal(s) to the semiconductor die, the input terminal being coupled to a first end of a first bond wire, a second end of the first bond wire being coupled to the semiconductor die, a first end of a second bond wire being coupled to the semiconductor die, a second end of the second bond wire being coupled to the output terminal.

18. The packaged semiconductor device as recited in claim 17, further comprising a path length from the input terminal to the output terminal of a fraction of the wavelength for which frequency the semiconductor device is designed.

19. The packaged semiconductor device as recited in claim 1, further comprising a controlled dielectric constant encapsulant operable to provide improved unit-to-unit and run-to-run package parasitic consistency.

20. The packaged semiconductor device as recited in claim 1, further comprising a light emitting semiconductor as the semiconductor die.

21. The packaged semiconductor device as recited in claim 20, further comprising a light emitting diode as the light emitting semiconductor.

22. The packaged semiconductor device as recited in claim 20, further comprising a substantially clear epoxy material as the encapsulant.

23. The packaged semiconductor device as recited in claim 20, further comprising a cathode and an anode as the plurality of leads.

24. The packaged semiconductor device as recited in claim 23, further comprising the positioning of the cathode and the anode opposite to each other.

25. The packaged semiconductor device as recited in claim 24, further comprising an encapsulant with a substantially hexagonal structure around the cathode and the anode essentially at right angles with respect to the substrate.

26. The packaged semiconductor device as recited in claim 23, further comprising a portion of a conductive lead-frame as the cathode.

27. The packaged semiconductor device as recited in claim 23, further comprising a shaped end surface of the cathode operable to minimize parasitic capacitance.

28. The packaged semiconductor device as recited in claim 27, further comprising a rounded shape on the end surface of the cathode.

29. The packaged semiconductor device as recited in claim 23, further comprising metallization as the cathode coupling means to the semiconductor die.

30. The packaged semiconductor device as recited in claim 23, further comprising a bond wire as the means of coupling the cathode to the semiconductor die, a first end of the bond wire being coupled to the cathode and a second end of the bond wire being coupled to the semiconductor die.

31. The packaged semiconductor device as recited in claim 23, further comprising a portion of a conductive lead-frame as the anode.

32. The packaged semiconductor device as recited in claim 23, further comprising a shaped end surface of the anode operable to minimize parasitic capacitance.

33. The packaged semiconductor device as recited in claim 32, further comprising a rounded shape on the end surface of the anode.

34. The packaged semiconductor device as recited in claim 23, further comprising metallization as the anode coupling means to the semiconductor die.

35. The packaged semiconductor device as recited in claim 23, further comprising a bond wire as the means of coupling the anode to the semiconductor die, a first end of the bond wire being coupled to the anode and a second end of the bond wire being coupled to the semiconductor die.

36. The packaged semiconductor device as recited in claim 23, further comprising a bond wire as the means of coupling the anode to the semiconductor die, a first end of the bond wire being coupled to the anode and a second end of the bond wire being coupled to the semiconductor die.

37. The packaged semiconductor device as recited in claim 20, further comprising being adapted for use in an integrated circuit.

38. The packaged semiconductor device as recited in claim 20, further comprising being adapted for use in a surface mount assembly.

39. The packaged semiconductor device as recited in claim 20, having length and width dimensions of approximately 0.079 millimeters and 0.050 millimeters and a height dimension of approximately 0.032 millimeters.

40. A packaged semiconductor device, comprising:
a light emitting semiconductor, a substrate, an anode, a cathode and an encapsulant material;
the light emitting semiconductor being disposed in the substrate;
a means of coupling the anode to the light emitting semiconductor;
a means of coupling the cathode to the light emitting semiconductor;
a substantially clear encapsulant for encapsulating the light emitting semiconductor, the encapsulant formed of a substantially hexagonal structure around the anode and the cathode with respect to the substrate, the encapsulant material acting as a thermal shunt to ground operable to decrease thermal capacitance and thermal resistance.

41. The packaged semiconductor device as recited in claim 40, adapted for use in a surface mount assembly.

42. A packaged semiconductor device, comprising:
a semiconductor die, a substrate and a plurality of leads;
the semiconductor die being disposed in the substrate;
a coupling means from the plurality of leads to the semiconductor die for providing low capacitance electrical connections which supports device functionality; and
an encapsulation material surrounding the semiconductor die, plurality of leads and coupling means, the encapsulation material making contact with the substrate operable to allow direct dissipation shunting to thermal ground.

43. The packaged semiconductor device as recited in claim 42, adapted for use in a surface mount assembly.

44. The packaged semiconductor device as recited in claim 42, further comprising a controlled dielectric constant material for the encapsulation material operable to provide improved unit-to-unit and run-to-run package parasitic consistency.

45. A method of assembling a semiconductor device package, comprising:
disposing a semiconductor die in a substrate;
positioning a plurality of leads on opposing sides of the semiconductor die;
coupling the plurality of leads to the semiconductor die;
encapsulating the semiconductor die and plurality of leads in an encapsulant; and
forming and configuring the encapsulant so as to allow direct dissipation shunting to thermal ground.

46. The method of assembling a semiconductor device package as recited in claim 45, further comprising shaping the ends of the plurality of leads in a substantially rounded form operable to minimize parasitic capacitance.

47. The method of assembling a semiconductor device package as recited in claim 45, further comprising a light emitting semiconductor as the semiconductor die.

48. The method of assembling a semiconductor device package as recited in claim 45, further comprising a cathode and an anode as the plurality of leads.

49. The method of assembling a semiconductor device package as recited in claim 45, further comprising a substantially clear material as the encapsulant.

50. The method of assembling a semiconductor device package as recited in claim 45, further comprising the encapsulant having a substantially hexagonal structure essentially at right angles with respect to substrate operable to decrease thermal capacitance and thermal resistance.
